(19) United States
(12) Patent Application Publication
(10) Pub. No.: US 2009/0029548 A1
(43) Pub. Date: Jan. 29, 2009

(54) METHOD FOR REMOVING POLYMER RESIDUE FROM METAL LINES OF SEMICONDUCTOR DEVICE

(76) Inventor: Chung-Kyung Jung, Anyang-si (KR)

Correspondence Address: SHERR & VAUGHN, PLLC, 620 HERNDON PARKWAY, SUITE 200, HERNDON, VA, 20170, US

(21) Appl. No.: 12/180,296

(22) Filed: Jul. 25, 2008

(30) Foreign Application Priority Data
Jul. 26, 2007 (KR) 10-2007-0075046

(51) Int. Cl. H01L 21/3205; H01L 21/67

(52) U.S. Cl. 438/669; 29/25.01; 257/E21.295

(57) ABSTRACT

It is possible to substantially remove a polymer residue from metal lines formed over a semiconductor device without damage to the metal lines. The disclosed method includes forming a metal layer over a lower layer. A photoresist film is formed over the metal layer, and then patterned. The metal layer is selectively etched, using the patterned photoresist film as an etch barrier, to form metal lines. A substantial portion of the photoresist film left on the metal lines is removed, leaving a polymer residue. Ultraviolet rays are irradiated onto the metal lines to degrade the polymer residue, and the residue is rinsed away.

The present application claims priority under 35 U.S.C. 119 to Korean Patent Application No. 10-2007-0075046 (filed on Jul. 26, 2007), which is hereby incorporated by reference in its entirety.

### BACKGROUND

Various polymer-containing materials are used in the manufacture of electronic devices, for example, integrated circuits, disc drives, storage mediums, etc. Such polymer-containing materials may be found in photoresist film, anti-reflective coatings, via-filling layers, etch stop layers, etc. In modem techniques, a photoresist material is used to form a desired pattern on a substrate for lithography, to perform etching processes using the pattern, or to transfer the pattern to the material of the substrate. The photoresist material is deposited in the form of a film. As the photoresist film is exposed to light, a desired pattern is defined. The light-exposed region is dissolved by a suitable developing solution, to transfer the pattern to the substrate. After the transfer of the pattern to the substrate, the photoresist material is removed from the substrate, in order to prevent the photoresist material from adversely affecting or interfering with a subsequent treatment or process.

The pattern definition (or pattern transfer) technique and polymer removal technique may often include at least one plasma processing procedure, for example, plasma etching, reactive ion etching, ion milling, plasma ashing, etc. In related cases, a plasma processing procedure is used in the manufacture of integrated circuits and other electronic devices. Generally, a polymer material is removed during the plasma processing procedure, irrespective of the amount of a polymer residue and other residues left on the substrate.

The residues may include an incompletely removed photoresist film, a side wall polymer left on the side walls of a line structure or in a recess such as a via, and an organic metal polymer and metal oxides left on the upper surface of the line structure or on the bottom of the recess. Such post plasma residues cannot be completely removed, using related photoresist film removal methods and rinsing processes.

The polymer residue left on metal lines may cause a bridge between the metal lines, and may adversely affect the electrical characteristics of the device. In particular, such problems may be more severe in a semiconductor device having a higher degree of integration.

FIG. 1 is a flow chart illustrating a method for forming metal lines in a semiconductor device and a method for removing polymer residue. A metal layer forming process S102 may be conducted to form a metal layer used to form metal lines over a lower layer. Thereafter, a photoresist film coating process S104 is conducted, for the execution of photo-lithography. In the photoresist film coating process S104, a photoresist film is formed over the entire upper surface of the metal layer.

Subsequently, a process S106 for etching the metal layer and removing a photoresist film residue is conducted. In this process, a pattern on a mask or reticle is transferred to the photoresist film, which is uniformly coated over, for example, a wafer, using exposing equipment such as a stepper in accordance with a stepped projection/exposure process. The photoresist film is then subjected to a developing process, to form a two-dimensional photoresist pattern. Using the photoresist film pattern as an etch barrier, the metal layer is etched to form metal lines. Thereafter, a photoresist film residue is removed.

A rinsing process S108 is then conducted. After the process S106 for etching the metal layer and removing the photoresist film residue, by-products in the form of polymer including carbon (C), silicon (Si), oxygen (O), etc. may be left on the metal lines. Such by-products may degrade the reliability of the product. For example, the by-products adversely affect the electrical connection of the lines. To this end, it is necessary to remove the by-products, through a rinsing process.

In a 130 nm technology, the line width of metal lines is reduced to about 160 nm. This tends to increase RC delays. To maintain the RC delay at a desired value, it is necessary to effectively remove a polymer residue left on the metal lines. In particular, where a reduced design rule is used, there may be a problem in that the polymer residue is mainly left on the upper surfaces of the metal lines, but not on the side walls of the metal lines.

If the metal line forming method and polymer residue removing method described above are used to remove the polymer residue as much as possible, the side walls of the metal lines, etc. may be damaged. This is because, although the maximal removal of the polymer residue can be achieved through an increase in the etching time or photoresist film removal time given in the metal layer etching/photoresist film residue removing process 106 or an increase in the rinsing time or rinsing intensity given in the rinsing process S108, damage to the side walls of the metal lines may also increase.

### SUMMARY

Embodiments relate to a method for removing a polymer residue from metal lines of a semiconductor device, and more particularly, to a method for removing a polymer residue formed in procedures of etching a metal layer for the formation of metal lines, removing a photoresist film, etc., without causing damage to the metal lines. Embodiments relate to a method for removing a polymer residue from metal lines of a semiconductor device, which is capable of removing a polymer residue formed in procedures of etching a metal layer for the formation of metal lines, removing a photoresist film, etc., without causing damage to the metal lines.

A method for removing a polymer residue from metal lines of a semiconductor device according to embodiments includes: forming a metal layer over a lower layer; forming a photoresist film over the metal layer, and patterning the photoresist film; selectively etching the metal layer, using the patterned photoresist film as an etch barrier, to form metal lines; removing a substantial portion of the photoresist film left on the metal lines; irradiating ultraviolet rays onto the metal lines, from which the substantial portion of the photoresist film has been removed; and rinsing the ultraviolet-irradiated metal lines.

### DRAWINGS

FIG. 1 is a flow chart illustrating a related method for forming metal lines of a semiconductor device and a related method for removing a polymer residue.

FIG. 2 is a flow chart illustrating a method for forming metal lines of a semiconductor device and a method for removing a polymer residue according to embodiments.

FIGS. 3A to 3E are sectional views illustrating a procedure for forming metal lines of a semiconductor device and removing a polymer residue from the metal lines in accordance with embodiments.

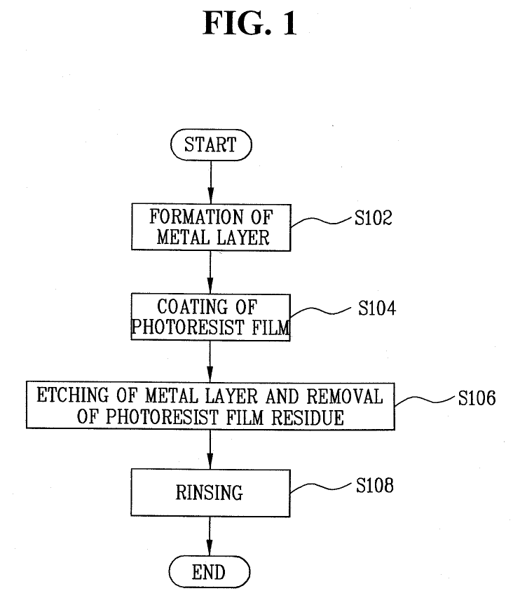

Example FIGS. 4A to 4C illustrate scanning electron microscopy (SEM) images for the comparison of the results of the polymer residue removal according to embodiments with the results of the general polymer residue removal.

### DESCRIPTION

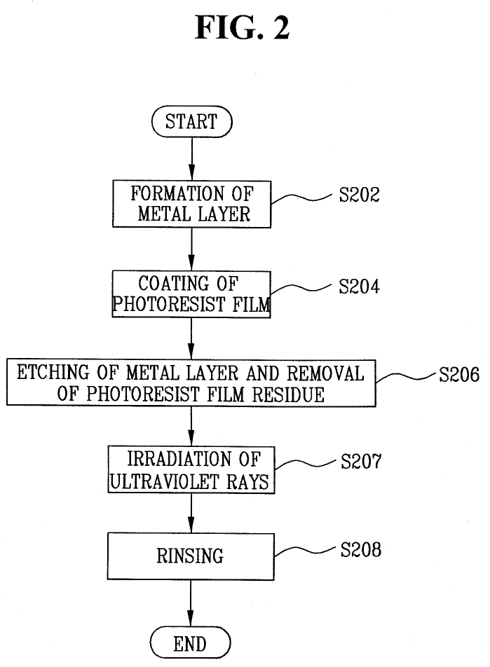

FIG. 2 is a flow chart illustrating a related method for forming metal lines of a semiconductor device and a related method for removing a polymer residue. In accordance with the related forming method, a metal layer forming process S202 is conducted to form a metal layer over a lower layer, for the formation of metal lines. The metal layer may be made of Ti, AlCu, or TiN.

Thereafter, a photoresist film coating process S204 is conducted, for the execution of photo-lithography. In the photoresist film coating process S204, a photoresist film is formed over the entire upper surface of the metal layer.

Subsequently, a process S206 for etching the metal layer and removing a photoresist film residue is conducted. In this process, a pattern on a mask or reticle is transferred to the photoresist film, which is uniformly coated over, for example, a wafer, using exposing equipment such as a stepper in accordance with a stepped projection/exposure process. The photoresist film is then subjected to a developing process, to form a two-dimensional photoresist pattern. Using the photoresist film pattern as an etch barrier, the metal layer is selectively etched to form metal lines. Thereafter, a photoresist film residue is removed.

For the photoresist film removing method, a dry ashing method using plasma may be used. For the selective etching of the metal layer, a reactive ion etching (RIE) method may be used.

Thereafter, an ultraviolet irradiation process S207 is conducted. When the ultraviolet irradiation is conducted after the metal layer etching/photoresist film residue removing process S206, but before a rinsing process for removing by-products such as a polymer residue, the polymer residue is deformed (or, in other words, degraded or decomposed) into a material capable of being easily removed without causing damage to metal lines.

The patterning of the photoresist film and the etching of the metal layer are carried out with the amounts of Cl₂ and CHF₃ gas adjusted in accordance with the width and depth of the photoresist film. Since polymer such as AlₓC_{y}Cl_{z} produced in the form of by-products is hardened polymer, it is difficult to remove the polymer, even when the rinsing time in the subsequent rinsing process increases. In this case, damage to the metal lines may occur.

When the rinsing time decreases, but the etching time for the metal layer increases, a line-shaped polymer may be formed on the metal lines, creating problems. To solve these problems, research on various gases usable in the etching process and various chemicals usable in the rinsing process has been conducted. However, most new methods developed to solve the above-mentioned problems cause another problem, for example, degradation in productivity, degradation in efficiency, or increases in costs.

To this end, embodiments are directed towards an ultraviolet irradiation method. In embodiments, Ti, AlCu, and TiN are examples of the metal layer. The ultraviolet irradiation method will be described in conjunction with one example of the metal layer, for example, Ti. Since Ti can be easily oxidized, a TiO_{X} layer is formed to a thickness of about 10 Å to 20 Å over the metal layer.

When ultraviolet rays are irradiated after the metal layer etching/photoresist film residue removing process S206, the TiO_{X} layer functions as a photo-catalyst layer on the surfaces of the metal lines formed in accordance with the etching of the metal layer. That is, the TiO_{X} layer reacts with a polymer residue left on the surface of the metal lines, thereby oxidizing the polymer residue into CO₂ and H₂O. The CO₂ and H₂O produced in accordance with the oxidation are materials capable of being easily removed in the subsequent rinsing process. In other words, the polymer left on the metal lines irradiated with the ultraviolet rays generates a photo oxidation, together with the photo-catalyst layer formed on the surfaces of the metal lines.

In accordance with embodiments, a preliminary rinsing process may be additionally conducted between the metal layer etching/photoresist film residue removing process S206 and the ultraviolet irradiation process S207. Thereafter, a rinsing process S208 is conducted. This process is used to remove by-products left after the metal layer etching/photoresist film residue removing process S206 and the ultraviolet irradiation process S207 in accordance with a rinsing method.

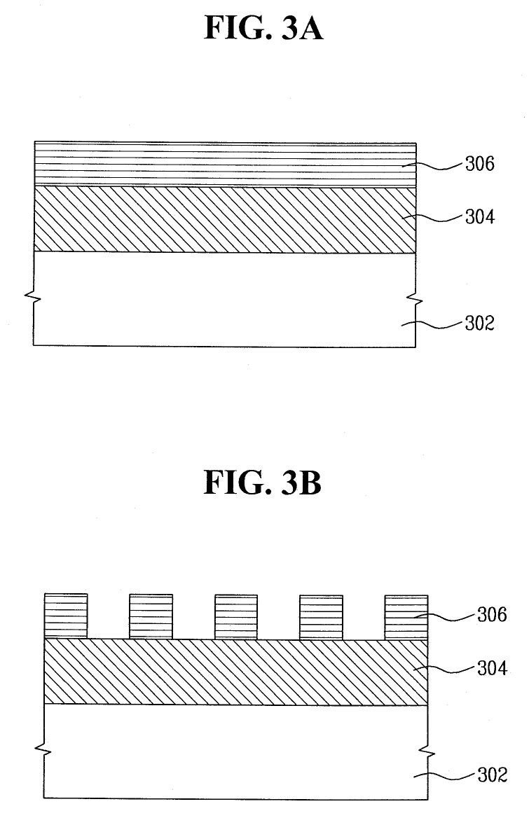

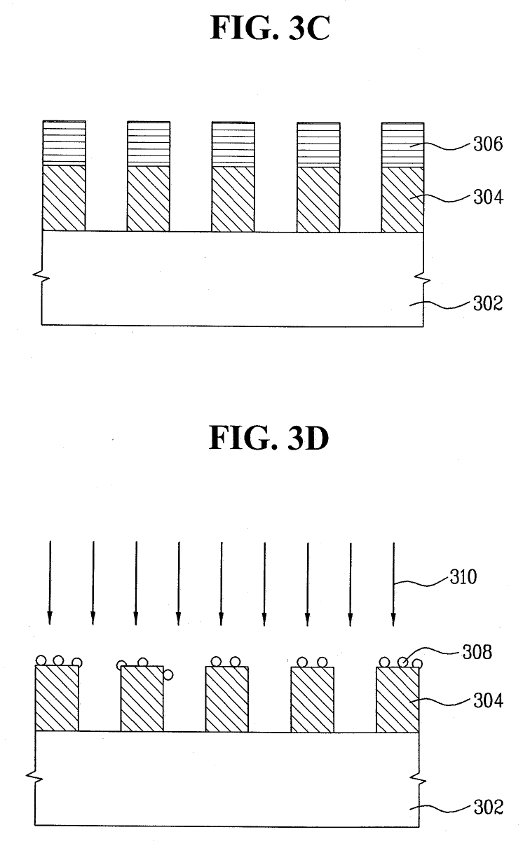

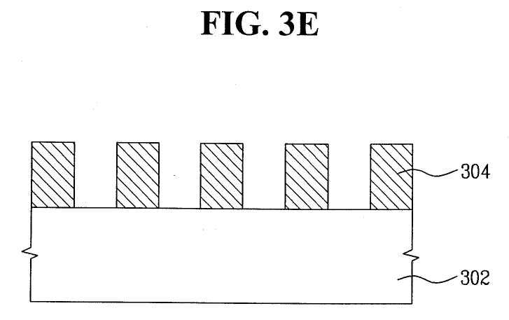

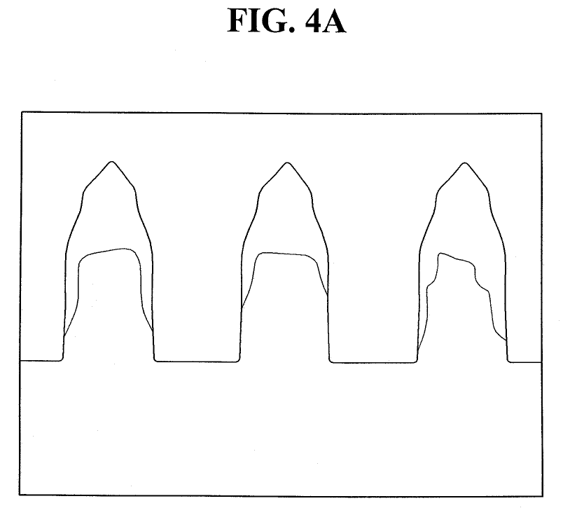

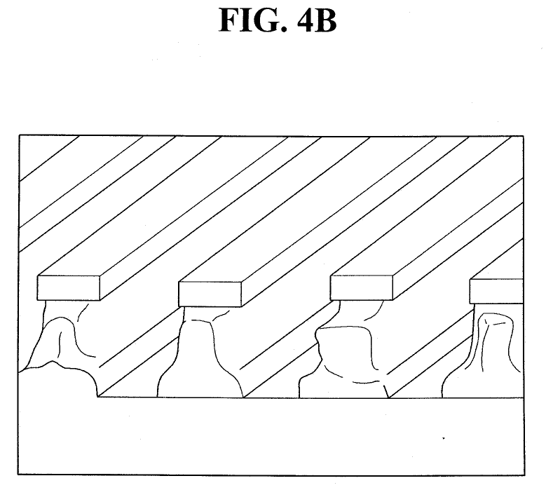

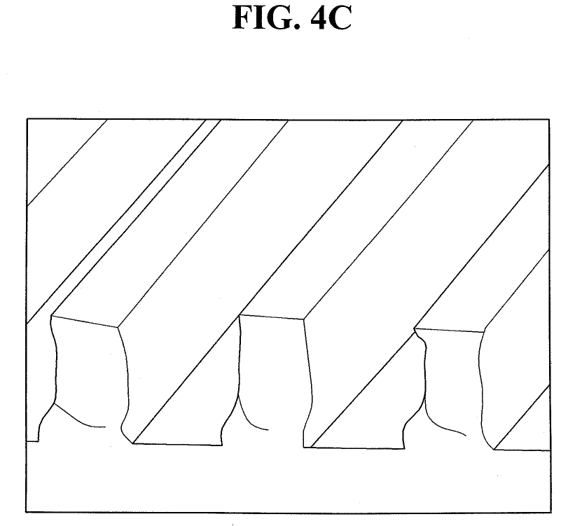

Example FIGS. 3A to 3E are sectional views illustrating a procedure for forming metal lines of a semiconductor device and removing a polymer residue from the metal lines in accordance with embodiments. Referring to example FIG. 3A, a metal layer 304 is formed over a lower layer 302 formed over a semiconductor substrate, and a photoresist film 306 is then coated over the metal layer 304. Thereafter, the photoresist film 306 is patterned to form a metal line pattern, as shown in example FIG. 3B. Using the patterned photoresist film 306 as an etch barrier, the metal layer 304 is then selectively etched to form metal lines, as shown in example FIG. 3C.

Thereafter, the photoresist film 306 left after the formation of the metal lines is removed, as shown in example FIG. 3D. In this state, a polymer residue 308 is left mainly on the upper surface of the patterned metal layer 304, namely, the upper surfaces of the metal lines. In order to effectively remove the polymer residue 308, the whole area is irradiated with ultraviolet rays 310.

The irradiation of the ultraviolet rays 310 is conducted with power at 0.5 mW/cm² to 1.3 mW/cm² and a wavelength of 220 nm to 365 nm. The metal layer 304 may be made of Ti, AlCu, or TiN. Where the metal layer is made of, for example, Ti, a TiO_{X} layer is formed to a thickness of about 10 Å to 20 Å over the metal layer because Ti can be easily oxidized.

The ultraviolet rays 310 activate a photo oxidation on the surface of the metal layer 304 to remove the polymer residue 308. The use of power at 0.5 mW/cm² to 1.3 mW/cm² and a wavelength of 220 nm to 365 nm correspond to minimal energy causing the TiO_{X} layer present on the surface of the patterned metal layer 304 to react with the ultraviolet rays 310.

When the irradiated ultraviolet rays 310 have a wavelength of 365 nm or shorter, electrons are excited from a valence band to a conduction band, even when they have optical band gap energy. As a result, the electrons and holes are activated. Using energy generated in accordance with the activation, the TiO_{X} layer conducts a photo oxidation with the hardened polymer residue 308 left on the surfaces of the metal lines through a catalyst reaction. At this time, no reaction occurs at the TiO_{X} layer itself. Thus, the polymer residue 308 is oxidized into CO₂ and H₂O. The ultraviolet rays 310 may have a wavelength of 220 nm to 380 nm.

The residue left after being subjected to the above-described process can be easily removed in the subsequently rinsing process, using many chemicals. Referring to example FIG. 3E, it can be seen that the surfaces of the patterned metal layer 304, in particular, the upper surface, are in a cleaned state without any polymer residue, after being subjected to the rinsing process.

Example FIGS. 4A to 4C are illustrations of scanning electron microscopy (SEM) images for the comparison of the results of the polymer residue removal according to embodiments with the results of the general polymer residue removal. Example FIG. 4A is an illustration showing the state after the etching of the metal layer, but before the removal of the photoresist film. Referring to example FIG. 4A, the photoresist film is left on the patterned metal layer, namely, on the upper surfaces of the metal lines, but no or little photoresist film is left on the side walls of the metal lines. If the etching of the metal layer is changed to increase the etch depth, in order to effectively remove the photoresist film, damage to the metal lines formed in accordance with the etching of the metal layer may occur. Otherwise, a variation in profile occurs. Also, if the subsequent rinsing process is conducted at a higher intensity, damage to the metal lines may occur.

If the etch depth or rinsing intensity is reduced to prevent the side walls of the metal lines from being damaged, a large amount of polymer residue is left on the upper surfaces of the metal lines, as shown in example FIG. 4B. In this case, the reliability of the semiconductor device is degraded.

When ultraviolet rays are irradiated after the removal of the photoresist film, and a rinsing process is conducted in accordance with embodiments, to solve the above-described problems, there is no polymer residue left on the upper surfaces of the metal lines, as shown in example FIG. 4C. In this case, it is possible to optimize the process without any damage to the metal lines. As apparent from the above description, the metal line polymer residue removing method according to embodiments can remove a polymer residue as much as possible without causing damage to the metal lines, by conducting an ultraviolet irradiation process after the etching of the metal layer and the removal of the leftover photoresist film.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a metal layer over a lower layer over a semiconductor substrate;
forming a photoresist film over the metal layer, and patterning the photoresist film;
selectively etching the metal layer, using the patterned photoresist film as an etch barrier, to form metal lines;
removing a substantial portion of the photoresist film left on the metal lines;
irradiating ultraviolet rays onto the metal lines, from which the substantial portion of the photoresist film has been removed; and
rinsing the ultraviolet-irradiated metal lines.

2. The method of claim 1, comprising performing a preliminary rinse after the removal of the substantial portion of the photoresist film left on the metal lines, and before irradiating the ultraviolet rays.

3. The method of claim 1, wherein removing the photoresist film left on the metal lines comprises an ashing method using plasma.

4. The method of claim 1, wherein the metal layer comprises AlCu.

5. The method of claim 1, wherein the metal layer comprises Ti.

6. The method of claim 1, wherein the metal layer comprises TiN.

7. The method of claim 1, wherein the selective etching of the metal layer is conducted using a reactive ion etching method.

8. The method of claim 1, wherein the ultraviolet rays irradiated onto the metal lines have a wavelength between about 220 nm to 380 nm.

9. The method of claim 1, wherein a polymer present on the metal lines irradiated with the ultraviolet rays oxidizes in a reaction with a photo-catalyst layer formed on surfaces of the metal lines.

10. The method of claim 9, wherein the photo-catalyst layer formed on the surfaces of the metal lines comprises a TiO_{X} layer.

11. The method of claim 10, wherein the reaction causes polymer residue present on the metal lines irradiated with the ultraviolet rays and the TiO_{X} layer to convert into CO₂ and H₂O.

12. The method of claim 11, wherein the CO₂ and H₂O are removed in the subsequent rinsing step.

13. The method of claim 9, wherein the reaction is a photo oxidation reaction.

14. The method of claim 9, wherein the photo-catalyst layer formed on the surfaces of the metal lines has a thickness of about 10 Å to 20 Å.

15. The method of claim 1, wherein the ultraviolet rays irradiated onto the metal lines have a wavelength of about 220 nm to 365 nm.

16. The method of claim 15, wherein the ultraviolet rays irradiated onto the metal lines have a power of about 0.5 mW/cm² to 1.3 mW/cm².

17. The method of claim 1, wherein rinsing the ultraviolet-irradiated metal lines removes a polymer residue.

18. The method of claim 1, wherein after removing a substantial portion of the photoresist film left on the metal lines, a hardened polymer residue remains on the metal lines.

19. The method of claim 19, wherein the ultraviolet rays degrade the hardened polymer residue for removal.

20. An apparatus configured to:
form a metal layer over a lower layer over a semiconductor substrate;
form a photoresist film over the metal layer, and pattern the photoresist film;
selectively etch the metal layer, using the patterned photoresist film as an etch barrier, to form metal lines;
remove a substantial portion of the photoresist film left on the metal lines;
irradiate ultraviolet rays onto the metal lines, from which the substantial portion of the photoresist film has been removed; and
rinse the ultraviolet-irradiated metal lines.
